(19) United States
(12) Patent Application Publication
(10) Pub. No.: US 2008/0309521 A1
(43) Pub. Date: Dec. 18, 2008

(54) MOBILE COMMUNICATION APPARATUS AND KEYPAD INPUT METHOD

(75) Inventors: Na ZHANG, Shenzhen (CN); Geng-Liang ZHANG, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Taipei Hsien (TW)

(21) Appl. No.: 11/966,974

(22) Filed: Dec. 28, 2007

(30) Foreign Application Priority Data
Jun. 14, 2007 (CN) 200710200818.8

(51) Int. Cl. H03K 17/94; H04M 11/00

(52) U.S. Cl. 341/22; 455/556.1

(57) ABSTRACT

A mobile communication apparatus comprising: a plurality of input keys for receiving a user inputs for performing functions of the mobile communication apparatus; a plurality of touch sensors configured on surfaces of the keys for sensing touches and generating a sensor signal; a controller for generating a command according to the sensor signal; and a player for reading a sound file according to the command, and outputting sound corresponding the sound file to a speaker. A related keypad input method is also disclosed.

### BACKGROUND

1. Field of the Invention

The present invention generally relates to communication apparatus. Particularly, the present invention relates to a mobile communication apparatus and a keypad input method.

2. Description of Related Art

Mobile phones are commonly used communication tools. The mobile phones are important to the visually impaired. The visually impaired can use the mobile phones for verbal communication.

Generally, the numbers on the keys of mobile phones are produced by printing or injecting using various materials with different colors. The numbers are easy to see and press by normal people. However, it is hard for the visually impaired to see and press the keys, because they cannot see the keys.

Consequently, a mobile communication apparatus and keypad input method facilitate using for the visually impaired are needed.

### SUMMARY

A mobile communication apparatus comprising: a plurality of input keys for receiving a user inputs for performing functions of the mobile communication apparatus; a plurality of touch sensors configured on the surface of each key for sensing touches and generating a sensor signal; a controller for generating a command according to the sensor signal; and a player for reading a sound file according to the command, and outputting sound, corresponding to the sound file, to a speaker.

A keypad input method comprising: generating a sensor signal when detecting a touch of a user on a key; generating a command according to the sensor signal; reading a sound file according to the command; outputting sound corresponding to the sound file; generating a press signal according to a user input generated by pressing the key; and performing functions corresponding to the key that is pressed according to the press signal.

Other apparatus, methods, features, and advantages of the present mobile communication apparatus and keypad input method will be or become apparent to one with skill in the art upon examination of the following drawings and detailed description. It is intended that all such additional apparatus, methods, features, and advantages be included within this description, be within the scope of the present apparatus and method, and be protected by the accompanying claims.

### BRIEF DESCRIPTION OF THE DRAWINGS

Many aspects of the present apparatus and method can be better understood with reference to the following drawings. The components in the drawings are not necessary to scale, emphasis instead being placed upon clearly illustrating the principles of the inventive apparatus and method. Moreover, in the drawings, like reference numerals designate corresponding parts throughout the several views.

FIG. 1 is a front view of the mobile communication apparatus according to an exemplary embodiment;

FIG. 2 is a schematic, block diagram of the mobile communication apparatus of FIG. 1;

FIG. 3 is a schematic diagram of the touch sensor of the mobile communication apparatus of FIG. 1; and

FIG. 4 is a flow chart diagram of a keypad input method according to an exemplary embodiment.

### DETAILED DESCRIPTION OF THE EMBODIMENTS

Reference will now be made to the drawings to describe exemplary and preferred embodiments of the present mobile communication apparatus and the present keypad input method.

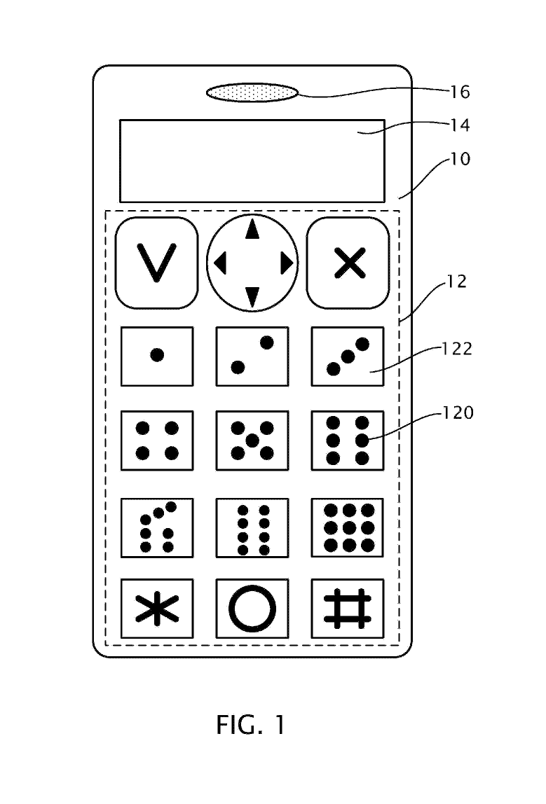

Referring to FIG. 1, a mobile communication apparatus 10 includes a keypad 12, a display 14, and a speaker 16.

The keypad 12 includes ten numbered input keys corresponding the numbers 0˜9, and a number of function keys. The keypad 12 is used for generating a press signal in response to a user input, for launching a program of the mobile communication apparatus 10. A plurality of protrusions 120 and a plurality of touch pieces 122 are configured on a surface of each of the keys. The protrusions 120 on each of the keys form the Braille code corresponding to the key. In other embodiments, the protrusions 120 can form other standard codes or predefined codes as well. The touch pieces 122 are set on the surface of a key or on the protrusions 120. The touch pieces 122 are used for sensing touches on a corresponding numbered input key. The speaker 16 is used for outputting sound corresponding to touched numbered input keys.

The display 14 is used for displaying suggestive information. The display 14 is adopted for the visually abled to use the mobile communication apparatus 10.

The speaker 16 is used for outputting sound, the sound includes suggestive sounds, the vocal input of the party on the other side of the line during a call, voice messages, or music, etc.

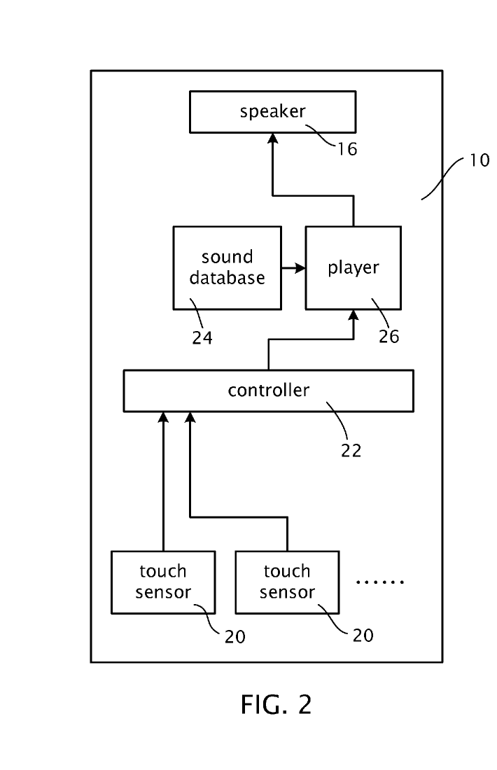

Referring to FIG. 2, a block diagram of the mobile communication apparatus of FIG. 1 is illustrated. The mobile communication apparatus 10 includes a plurality of touch sensors 20, a controller 22, a voice database 24, a player 26, and the speaker 16.

The touch sensor 20 is used for detecting touches and generating the sensor signals. The sensor signals are sent to the controller 22.

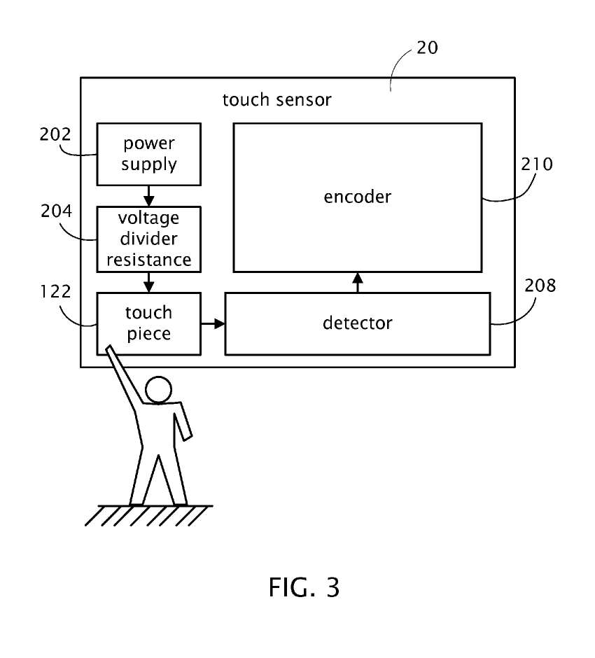

Referring to FIG. 3, the touch sensor 20 includes a power supply 202, a voltage divider 204, a plurality of touch pieces 122, a detector 208, and an encoder 210. The power supply 202 is used for providing a voltage for the voltage divider 204. The voltage divider 204, and each touch piece 122 which is serially connected to the voltage divider 204, are used for dividing a voltage applied thereon. In an exemplary embodiment, the voltage divider 204 is a resistor. The touch pieces 122 are made of tinplate. When the user touches the touch pieces 122, the user is connected to ground acting as a conductor. Accordingly, a current is generated from the power supply 202 to flow through the voltage divider 204, the touch piece 122, the user, and finally to ground. The detector 208 is used for detecting the current, and generating an impulse signal according to the current. The encoder 210 is used for encoding the impulse signal with corresponding function information of the keys, and generating the sensor signal.

The controller 22 is used for generating a command according to the sensor signal, and sending the command to the player 26.

The sound database 24 stores sound files corresponding to the keys. The sound database includes the sound file for each of the numbered keys, the sound file for the enter key, the cancel key, the star (asterisk) key, the hash (pound) key, and so forth.

The player 26 is used for reading the sound file according to the command, and outputting sound corresponding to the sound file via the speaker 16.

In one embodiment, the touch sensor 20 can be a capacitive touch sensor. The capacitive touch sensor includes a capacitor, and one electrode of the capacitor is provided with a sinusoidal wave signal. When conductors, such as fingers of the users, touch one of the electrodes of the capacitor, the voltage on the capacitor is changed. By detecting the voltage of the other electrode of the capacitor, the sensor signal can be generated accordingly. In other embodiments, the touch sensor 20 can also be an interferential touch sensor, which is able to generate the sensor signal according to a noise wave based on the touches of the user.

When operating, the keys of the keypad 12 are gently touched first before pressing the keys. The mobile communication apparatus 10 detects which of the keys is being gently touched and outputs the suggestive sound correspondingly. In other words, the mobile communication apparatus 10 vocally guides a user to a desired key with the touch pieces 122 and sound files so that the user can accurately press the desired key, thus improving operation efficiency and avoiding input mistakes. The mobile communication apparatus 10 provides a user interface to facilitate and operate the mobile communication apparatus 10 for the visually impaired.

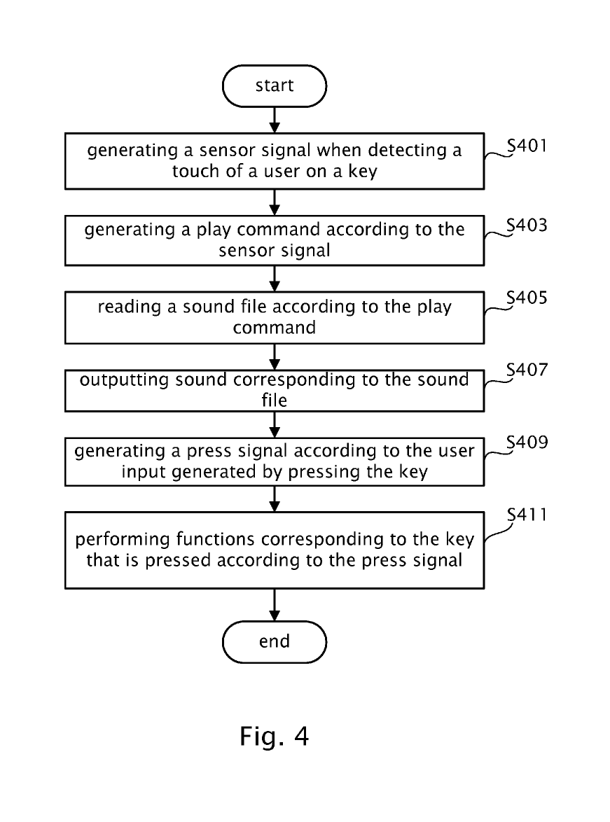

Referring to FIG. 4, a keypad input method in accordance with an exemplary embodiment includes following steps:

Step S401, generating a sensor signal when detecting a touch of a user on a key.

Step S403, generating a command according to the sensor signal. The sensor signal is generated by a touch sensor includes a power supply for supplying power, a voltage divider electrically connected to the power supply, and a plurality of touch pieces electrically connected to the voltage divider. The touch pieces formed on the key. A current is generated from the power supply to flow through the voltage divider, the plurality of the touch pieces, the user, and finally to ground when the user touches the plurality of the touch pieces. The each touch sensor further comprises a detector for detecting the current, and generating an impulse signal according to the current, and an encoder for encoding the impulse signal and generating the sensor signal.

Step S405, reading a sound file according to the command.

Step S407, outputting sound corresponding to the sound file.

Step S409, generating a press signal according to the user input generated by pressing the key.

Step S411, performing functions corresponding to the key that is pressed according to the press signal.

According to the above keypad input method, it can senses the touch and outputs the suggestion sound before pressing the keys, thus remind users of the key that they are going to press, which improving operation efficiency and avoiding input mistakes.

What is claimed is:

1. A mobile communication apparatus comprising:
a plurality of input keys for receiving a user inputs for performing functions of the mobile communication apparatus;
a plurality of touch sensors configured on surfaces of the keys for sensing touches and generating a sensor signal;
a controller for generating a command according to the sensor signal; and
a player for reading a sound file according to the command, and outputting sound, corresponding to the sound file, to a speaker.

2. The mobile communication apparatus as claimed in claim 1, wherein each key comprises a plurality of protrusions, the protrusions being Braille code.

3. The mobile communication apparatus as claimed in claim 2, wherein each key further comprises a touch piece set on a surface of the key.

4. The mobile communication apparatus as claimed in claim 2, wherein the each key further comprises a touch piece set on the protrusion.

5. The mobile communication apparatus as claimed in claim 1, wherein the touch sensors senses the touches by detecting currents flowing from the keys to the user touching the keys.

6. The mobile communication apparatus as claimed in claim 1, wherein each touch sensor comprises a power supply for supplying power, a voltage divider electrically connected to the power supply, and a plurality of touch pieces electrically connected to the voltage divider, wherein a current generated by the power supply flows though the voltage divider, the touch pieces, the user, and finally to ground when the user touches the touch pieces.

7. The mobile communication apparatus as claimed in claim 6, wherein the each touch sensor further comprises a detector for detecting the current, and generating an impulse signal according to the current, and an encoder for encoding the impulse signal and generating the sensor signal.

8. The mobile communication apparatus as claimed in claim 1, wherein each touch sensor is a capacitive touch sensor comprising a capacitor, and one electrode of the capacitor is provided with a sinusoidal wave signal.

9. The mobile communication apparatus as claimed in claim 1, wherein each touch sensor is an interferential touch sensor for generating the sensor signal according to a noise wave when being touched by the user.

10. A keypad input method comprising:
generating a sensor signal when detecting a touch of a user on a key;
generating a command according to the sensor signal;
reading a sound file according to the command;
outputting sound corresponding to the sound file;
generating a press signal according to a user input generated by pressing the key; and
performing functions corresponding to the key that is pressed.

11. The keypad input method as claimed in claim 10, wherein the sensor signal is generated by a touch sensor comprising a power supply for supplying power, a voltage divider electrically connected to the power supply, and a plurality of touch pieces electrically connected to the voltage divider.

12. The keypad input method as claimed in claim 1, wherein the touch pieces are formed on the key.

13. The keypad input method as claimed in claim 12, wherein a current generated by the power supply flows though the voltage divider, the touch pieces, the user, and finally to ground when the user touches the touch pieces.

14. The keypad input method as claimed in claim 13, wherein the each touch sensor further comprises a detector for detecting the current, and generating an impulse signal according to the current, and an encoder for encoding the impulse signal and generating the sensor signal.
